(19) United States
(12) Patent Application Publication
(10) Pub. No.: US 2016/0014878 A1
(43) Pub. Date: Jan. 14, 2016

(54) THERMAL MANAGEMENT CIRCUIT MATERIALS, METHOD OF MANUFACTURE THEREOF, AND ARTICLES FORMED THEREFROM

(71) Applicant: Rogers Corporation, Rogers, CT (US)

(72) Inventor: Brett W. Kilhenny, Mystic, CT (US)

(21) Appl. No.: 14/692,981

(22) Filed: Apr. 22, 2015

Related U.S. Application Data
(60) Provisional application No. 61/984,259, filed on Apr. 25, 2014.

(51) Int. Cl. H05K 1/02; H05K 1/09; H05K 1/11; H01L 33/62; H05K 3/32; H05K 3/40; H05K 3/44; H05K 3/00; H05K 3/12; H05K 1/03; H01L 33/64

(52) U.S. Cl. CPC H05K 1/0201; H05K 1/03; H05K 1/09; H05K 1/0298; H05K 1/115; H01L 33/62; H01L 33/647; H01L 33/641; H05K 3/4038; H05K 3/44; H05K 3/0094; H05K 3/0097; H05K 3/12; H05K 3/32; H05K 2203/1338; H01L 2933/0066; H01L 2933/0075

(57) ABSTRACT

A thermal management circuit material comprises a thermally conductive metallic core substrate having at least one through-hole via, non-metallic dielectric layers deposited on both sides of the metallic core substrate and on the containing walls of the through-hole via, electrically conductive metal layers on the non-metallic dielectric layers and an electrically conductive metal-containing core element filling the insulated through-hole via connecting at least a portion of each of the electrically conductive metal layers. Also disclosed are methods of making such circuit materials, comprising forming non-metallic dielectric layers by vapor deposition of a non-metallic material, for example by reacting an oxygen-containing precursor with an aluminum containing precursor and/or reacting a nitrogen-containing precursor with an aluminum or boron containing precursor on the surface of the metallic core substrate. Articles having a heat-generating electronic device such as an HBLED mounted in the circuit material are also disclosed.

### BACKGROUND

This invention relates to thermal management circuit materials comprising one or more electrically conductive vias. Such circuit materials can be used to support optoelectronic, microwave, RF, power semiconductor, or other electronic devices.

While there are a variety of circuit materials available today, there is especially a demand for circuit materials for high power applications, that is, applications generating high specific energy or involving high operating temperature. In particular, semiconductors that are designed to carry relatively high current loads can have an upper limit for operating temperatures, above which the semiconductor can fail, jeopardizing the operational reliability of the entire circuit. Circuit materials designed for thermal management have been used where there is a need to dissipate heat, in order to maintain the operating temperature in a desired range. Such heat-dissipating thermal management circuit materials can be useful with high power diodes, transistors, or the like. For example, optoelectronic, microwave, RF, switching, amplifying, or other electronic device can be mounted on a substrate that provides support and acts to remove heat from the device. Such a substrate requires both sufficient dielectric strength and a good thermal conductivity.

A thermal management circuit material typically has a thermally conductive base, or core substrate (typically a thermally conductive metal such as aluminum) for conducting heat away from a high power component. A dielectric layer insulates the core substrate from a patternable or patterned electrically conductive metal layer (typically a metal such as copper) disposed on the dielectric layer. Such a circuit material is sometimes referred to as an insulated metal substrate or IMS. It is known to insulate a thermally conductive base on one or both sides using a dielectric material. Such insulated metal substrates can also be referred to as Metal Core Printed Circuit Boards (MCPCB). Thermal management circuit materials can also comprise a substrate layer attached to a heat sink, optionally through a layer of thermal interface material. However, a thermal management circuit material can comprise a metal board or supporting frame, as a core substrate, with or without a separately configured heat sink.

The dielectric material on the thermal management circuit material should have a high dielectric strength to secure electric insulation from circuitry associated with the electronic device, thereby avoiding or preventing short-circuiting. The dielectric layer or layers disposed on a thermally conductive core substrate, however, can limit the desired thermal conductivity of the circuit material. Thus, the dielectric material should have sufficient thermal conductivity to dissipate heat generated by the device, which otherwise can negatively affect performance, reliability and lifetime of a device mounted on the circuit material. In general, a dielectric material having increased dielectric strength enables a circuit material to have a thinner insulating layer, which can reduce thermal resistance (with the same insulating material). Other electronic properties of a dielectric material can be relevant also. For instance, for RF and microwave applications it can also be beneficial that the thermal management circuit material comprises a dielectric material that has a high dielectric constant.

Variously many organic and inorganic dielectric materials are known in the prior art. In particular, it is known to insulate a thermally conductive base using a dielectric material that is polymeric, for example epoxy, fluoropolymer, polyimide or their composites charged with thermally conductive ceramic powders. Such polymeric dielectric materials, however, can have low thermal conductivities and, moreover, can exhibit insufficient thermal stability necessary for high operating temperatures, e.g., greater than 150° C.

On the other hand, inorganic dielectric materials can have higher thermal conductivity (typically greater than or equal to about 20 Watts per meter-degree Kelvin or W/m-K), low coefficients of thermal expansion (typically less than or equal to 10 parts per million per degree centigrade, ppm/° C.), and high thermal stability (e.g., up to about 900° C.). Inorganic dielectric materials can include, for example, aluminum nitride, aluminum oxide, beryllium oxide, silicon nitride, or the like.

An inorganic dielectric material, however, may require an adhesion-improving layer for sufficient adhesion to an overlying electrically conductive metal layer or an underlying metallic substrate surface. Likewise, an inorganic dielectric material may require an adhesion-improving layer for sufficient adhesion to the underlying metal substrate, depending on the dielectric material or process employed. Furthermore, inorganic dielectric materials can have lower dielectric strengths, typically less than or equal to about 20 kiloVolts per mm of dielectric thickness (V/mil) and, therefore, can require a relatively thick layer (greater than or equal to 10 mils/250 micrometers), which in turn can detract from thermal conductivity. This can be disadvantageous for applications that increasingly require smaller components and higher thermal conductivity. The dielectric strength of the inorganic material can depend on its process of manufacture, in which a dense and uniform layer is desired.

An inorganic dielectric layer for an insulated metal substrate can be obtained by various techniques. A dielectric layer can be formed directly on a heat sink by an anodizing process as described in GB 2162694 or by Plasma Electrolytic Oxidation (PEO) as described in US Pat. 2008257585A1 Shashkov et al., in WO 2012/107754, have disclosed a method of forming a non-metallic coating or layer on a metallic substrate in a deposition chamber by applying a sequence of voltage pulses of alternating polarity to electrically bias the metallic substrate with respect to an electrode. WO 2012/1077555, also to Shashkov et al., discloses that an insulated metal substrate, as made by the process of WO 2012/107754, can be used for supporting a device and can be affixed to a heat sink on one side. The ceramic dielectric coating on the insulated metal substrate can have a dielectric strength greater than 50 KV mm⁻¹ and a thermal conductivity of greater than 5 Wm⁻¹K⁻¹. Shashkov et al. show an insulated metal substrate (IMS), insulated on one side and having a heat sink on the other side, for use with a packaged device or chip such as an LED. Thermal vias through the ceramic coating can connect to the metal heat sink to provide further heat transfer. WO 2012/107754 generally discloses that such thermal vias can be formed by a masking process prior to the formation of the dielectric coating, by an etching process after the coating has been formed, or by laser ablation of the ceramic dielectric coating.

There is a need for thermal management circuit materials that are relatively thin and that have desired thermal and electrical properties for use with high power devices such as an HB LED (high-brightness light-emitting diode). In addition, it is desirable that such a thermal management circuit material be capable of being efficiently and economically made.

### SUMMARY

The above-discussed and other drawbacks and deficiencies of prior art thermal management circuit materials can be overcome or alleviated by a circuit material comprising a thermally conductive metallic core substrate; a first non-metallic dielectric layer on a first side of the metallic core substrate; a second non-metallic dielectric substrate layer on a second side of the thermally conductive metallic core substrate, which second side is opposite from the first side of the metallic core substrate; a first electrically conductive metal layer on the first non-metallic dielectric layer; a second electrically conductive metal layer on the second non-metallic dielectric layer; at least one though-hole via, in the metallic core substrate, filled with an electrically conductive metal-containing core element electrically connecting at least a portion of each of the first and second electrically conductive metal layers, wherein walls defining the through-hole via are covered with an intermediate non-metallic dielectric layer transversely joining the first non-metallic dielectric layer and the second non-metallic dielectric layer, which non-metallic dielectric layers insulate the metallic core substrate from the electrically conductive metal. Thus, the first, second, and intermediate non-metallic dielectric layers (collectively “non-metallic dielectric layers”) can form a continuous non-metallic dielectric overall layer (forming no holes in the dielectric layers that can cause a short circuit) insulating the thermally conductive metallic core substrate from the electrically conductive metal layers and the metal-containing core element in the through-hole via, wherein the dielectric layers are made by a process comprising depositing the non-metallic dielectric layers on the metallic core substrate by a process of deposition in which ceramicizing precursor compounds, in the form of a vapor or gas, react to form a solid non-metallic layer that is deposited, at the same time, on both sides of the metallic core substrate and on the containing walls of the electrically conductive through-hole vias. In one embodiment, the non-metallic dielectric layer can have a thermal conductivity of greater than or equal to about 5 Watt per meter-degree Kelvin and/or a dielectric strength of greater or equal to 20 KV mm⁻¹.

Optionally an outer adhesion-improving metallic seed layer, outer with respect to the non-metallic dielectric layer, can be present between the non-metallic dielectric layers and the electrically conductive metal layers.

Optionally an inner adhesion-improving layer, inner with respect to the non-metallic dielectric layer, is present between the metallic core substrate and the non-metallic dielectric layer. In one embodiment, the inner adhesion-improving layer is formed by electrolytically pretreating the metallic core substrate to oxidize a surface area portion of the metallic core substrate.

In particular, one aspect of the invention is directed to A thermal management circuit material, capable of use for mounting an electronic device, comprising: a thermally conductive metallic core substrate; a first non-metallic dielectric layer on a first side of the metallic core substrate; a second non-metallic dielectric substrate layer on a second side of the thermally conductive metallic core substrate, which second side is opposite from the first side of the metallic core substrate; a first electrically conductive metal layer on the first oxide non-metallic dielectric layer; a second electrically conductive metal layer on the second non-metallic dielectric layer; at least one through-hole via filled with an electrically conductive metal forming a metal-containing core element that electrically connects at least a portion of each of the first and second electrically conductive metal layers, wherein the walls defining the through-hole via have an intermediate non-metallic dielectric layer transversely joining the first non-metallic dielectric layer and the second non-metallic dielectric layer, which intermediate non-metallic dielectric layer insulates the metal-containing core element in the through-hole via from the thermally conductive metal core substrate; wherein the first, second, and intermediate non-metallic dielectric layers are made by a process comprising depositing the reaction product of volatile precursor compounds on at least a surface area portion of the metallic core substrate, wherein the deposited reaction product comprises a non-metallic compound selected from the group consisting of a metal oxide, metal nitride, boron oxide, boron nitride, and combinations.

Another aspect of the invention is directed to a method of making a circuit material comprising: providing a metallic core substrate that is thermally conductive; forming at least one through-hole via in the metallic core substrate; forming non-metallic dielectric layers on opposite sides and in through-hole vias of the metallic core substrate by depositing on the surface of the metallic core substrate a non-metallic material; and applying electrically conductive metal layers over the surface of the non-metallic dielectric layers at least on opposite sides of the metallic core substrate.

Still another aspect of the invention is directed to an article comprising an electronic device selected from the group consisting of an optoelectronic device such as an LED (light emitting diode), especially including HB LEDs (high-brightness LEDs), an RF device, a microwave device, a switching, amplifying or other electronic device supported on the above-described circuit material having a patterned electrically conductive layer, i.e. in which the circuit material is used for mounting an electronic device, for example, to obtain a packaged LED comprising an insulated substrate. The electronic device can be a heat-generating semiconductor, diode, or transistor.

Yet another aspect of the invention is directed to a method of making a circuit material comprising providing a thermally conductive metallic core substrate; forming (for example, drilling) at least one through-hole via in the metallic core substrate; forming non-metallic dielectric layers on opposite sides and in the through-hole vias of the metallic core substrate by a process comprising depositing, on a surface area of the metal of the metallic core substrate, a non-metallic layer; and subsequently applying an electrically conductive metal such as copper opposite sides of the insulated metallic core substrate. The resulting circuit material thus made can have a thermal conductivity of greater than or equal to about 50 Watt per meter-degree Kelvin.

One specific embodiment of the invention is directed to a method of making a circuit material comprising providing an aluminum core substrate; drilling a pattern of conductive through-hole vias in the aluminum core substrate; depositing dielectric layers of aluminum oxide, aluminum nitride, aluminum boride, or a combination thereof on opposite sides and in the vias of the aluminum core substrate, wherein the method comprises positioning the aluminum core substrate in an deposition chamber for depositing a non-metallic material by surface reaction of volatile precursor compounds, wherein at least a portion of the surface area on both sides of the aluminum core substrate and the internal walls of through-hole vias are exposed to the volatile precursor compounds for a predetermined period of time to effectively ceramicize at least a portion of the surface area of the aluminum core substrate, including the containing walls of the through-hole vias, after which the insulated surface area can be selectively plated with copper, optionally preceded by a metallic seed coating.

By “deposition” is meant a process in which material is added onto a surface, in this case a surface of the core meal substrate.

The thermal management circuit material can have a desirable combination of properties including, as provided by the non-metallic dielectric layers, relatively high thermal conductivity, low electrical conductivity, and high thermal and dimensional stability, wherein the combination of properties is superior to that found in comparable circuit materials. Advantageously, the circuit materials can also be provided in thin cross-section. Furthermore, the circuit materials can be made into larger panels, which can be later subdivided, resulting in a more economic process for making a superior product.

The features and advantages of the present invention will be appreciated and understood by those skilled in the art from the following detailed description and drawings.

### BRIEF DESCRIPTION OF THE DRAWINGS

Referring now to the exemplary drawings wherein like elements are numbered alike in the several FIGURES:

FIG. 1 is a perspective view of a thermal management circuit material according to one embodiment of the present invention;

FIGS. 2A, 2B, and 2C show a heat management circuit material that can be used for mounting an LED package according to one embodiment of the invention, wherein FIG. 2A to 2C are a top plan, bottom and sectional view, in which circuit material the core substrate has been drilled with a plurality of through-hole vias; and

FIGS. 3A and 3B are cross-sectional views of two alternative embodiments of a heat thermal management circuit material in which an LED device has been mounted.

### DETAILED DESCRIPTION

A thermal management circuit material can advantageously comprise a thermally conductive metallic core substrate having at least one through-hole via, non-metallic dielectric layers on opposite substantially flat sides of the metallic core substrate and on the containing walls of the through-hole via, electrically conductive metal layers on each of the non-metallic dielectric layers and an electrically conductive metal-containing core element filling the through-hole via and connecting at least a portion of each of the electrically conductive metal layers. The non-metallic dielectric layers on the metallic core substrate collectively form “non-metallic insulation” that insulates the metallic core substrate from the electrically conductive metal layers and the electrically conductive metal-containing core element in the through-hole via. Such non-metallic dielectric insulation can be made by a process comprising depositing the non-metallic insulation onto the surface of the metallic core substrate wherein a volatile aluminum and/or boron-containing precursor compound reacts with a volatile oxygen-containing precursor compound and/or nitrogen-containing precursor compound. Also disclosed are articles having an electronic device such as an HBLED mounted on the circuit material.

Another aspect of the present invention relates to a method of fabricating electronic devices that contain at least a layer comprising non-metallic oxide and/or nitride deposited by chemical vapor deposition (CVD) or atomic layer deposition (ALD). In one embodiment, aluminum oxide is deposited on an aluminum metallic core substrate. The present invention is also directed to article comprising an electronic device mounted on a thermal management circuit material.

The present invention broadly relates to CVD or ALD of oxides or nitrides that can ceramicize a metallic core substrate and to fabrication of an electronic devices incorporating a film deposited by such method

The deposition of a non-metallic dielectric material can be accomplished by a CVD or ALD process using conventional delivery means. The process is not limited to a specific CVD or ALD apparatus or delivery system. Chemical vapor deposition (CVD) is characterized by the introduction of multiple reagents into a reactor simultaneously, whereas atomic layer deposition (ALD) is characterized by the sequential introduction of multiple reagents into a reactor, including, but not limited to, atomic layer epitaxy, digital chemical vapor deposition, pulsed chemical vapor deposition, and other like methods. ALD may also be referred to as atomic layer CVD or cyclical deposition. CVD can be viewed as any and all chemical forms of deposition from the gas phase and, hence, ALD can be viewed as a form of CVD. On the other hand, when referring to CVD and ALD both together, ALD is used to distinguish from non-ALD forms of CVD. In any case, according to the present process, vapor deposition can be carried out by either what is known as chemical vapor deposition or atomic layer deposition, wherein both involve vapor deposition, with atomic layer deposition including vapor deposition comprising alternating layers having a thickness on or the order of molecular dimensions.

An ALD-type process refers to technologies that are more similar to ALD processes than to other deposition processes. If it is based on cycles, it can be classified under ALD. In some cases, processes performed with tools designed for other purposes can be used in an ALD process. For example, chemical vapor deposition CVD, molecular beam epitaxy (MBE), gas source MBE, organometallic MBE, and chemical beam epitaxy when performed with alternating pulses of precursor material(s) utilizing self-limiting features, can be classified as an ALD process for present purposes, not to make too fine a distinction among possible variations. In this application, therefore, atomic layer deposition, or the acronym ALD, includes also ALD-type processes, in which volatile precursors are deposited on a metallic surface in a cyclical process.

The term “layer” or “film” refers to a single layer or several layers of material. The thickness of the film depends on the application and can vary within a wide range. ALD is often used in connection with so called thin films. The thickness range for ALD can vary from one atomic layer up to a few tens of a micrometer. However, ALD technology can also be used for producing materials of a thickness up to tens of millimeters. For present purposes, the non-metallic insulation deposited on the metallic core substrate must have thickness of at least 50 nm and can be up to 50 micrometers in thickness, specifically 1 to 30 micrometers, more specifically 1 to 15 microns, in which the thickness is predetermined in order to obtain the desired voltage breakdown performance or other electrical characteristics for a given application requirements. Also, the thickens may vary based on the specific composition of the dielectric material. The films made by ALD have exceptional characteristics, such as being essentially pinhole free and possessing excellent step coverage even in structures with a very high aspect ratio. The ALD technique cam also allow for precise tailoring of material compositions and their properties for very thin films.

When referring to a non-metallic material, for example, an oxide or nitride, various chemical compositions and crystalline structures are encompassed. Where a stoichiometric chemical formula is used, as is common practice in the field, this does not necessarily imply that the layer in question has the corresponding absolute stoichiometric composition, but it can have a wide range of phases with varying metal/oxygen ratios.

More specifically, in one embodiment, the process can comprise CVD or ALD of aluminum oxide. Such a process can utilize an aluminum alkoxide precursor dissolved, emulsified or suspended in a liquid, vaporizing the aluminum alkoxide precursor so as to form a vaporized precursor, and depositing a constituent of the vaporized precursor on a substrate to form a film at an elevated temperature. In one embodiment, the deposition is carried out at a temperature of from about 500° to about 1200° C., following which the aluminum oxide film optionally can be annealed utilizing any conventional annealing process.

Specifically, an aluminum-containing precursor can be any aluminum alkoxide. A formula for such a precursor can be represented by Al(OR)₃ wherein R is a ligand selected from linear or branched C₁-C₁₂ alkyls. Aluminum alkoxide precursors that can be employed in the present invention include, but are not limited to, aluminum iso-propoxide, aluminum sec-butoxide, aluminum ethoxide, aluminum iso-butoxide, aluminum methoxide, aluminum neo-pentoxide, aluminum propoxide, aluminum butoxide, aluminum tertiary-butoxide, or aluminum phenoxide.

A liquid for dispersing the aluminum-containing precursor can be an organic solvent, for example, selected from aliphatic hydrocarbons, aromatic hydrocarbons, alcohols, ethers, aldehydes, ketones, acids, phenols, esters, amines, alkylnitriles, halogenated hydrocarbons, silylated hydrocarbons, thioethers, amines, cyanates, isocyanates, thiocyanates, silicone oils, nitroalkyls, alkylnitrates and/or mixtures of one or more of the above. The precursor may be dissolved, emulsified or suspended in the liquid using techniques well known to those skilled in the art.

Vaporization can be carried out by heating the aluminum-containing precursor and liquid to a temperature of from about 40° to about 250° C. for a time period sufficient to obtain a vaporized precursor. The vaporization can be carried out in the presence of an inert gas such as He, N₂ or Ar, which gas can also be used during the deposition of the aluminum oxide.

For example, in one embodiment of a process comprising atomic layer deposition, an aluminum core substrate can be placed in a deposition reactor such as are commercially available, and atomic layer deposition can be performed in a cyclic fashion with sequential alternating pulses of vaporized aluminum alkoxide, reactant and purge gas (and/or vacuum evacuation of reactor chamber before introduction of aluminum alkoxide or reactant).

Thus, an ALD process involves deposition of material onto a surface by means of a plurality of cycles. In a conventional ALD cycle, the reaction between two alternating precursors adds a new atomic layer to previously deposited layers to form a cumulative layer. The cycle can be repeated as many times as necessary to gradually form the desired layer thickness. Lately, more complex deposition cycles have been introduced such as disclosed, for example, in U.S. Pat. No. 8,367,56, describing a method to improve layer uniformity in ALD or ALD-type processes by using a metal halide as a first precursors with an oxygen-containing second precursor such as H₂O, H₂O₂ or tert-butanol, wherein a dose of ethanol or methanol is introduced as a “modificator” subsequent to a dose of the oxygen-containing precursor.

In another embodiment a nitride film can be made by CVD or ALD, for electrically insulating a metallic core substrate. Nitride films are commonly formed via chemical vapor deposition (CVD). During the formation of nitride films, a high energy source optionally can be used to break, or crack, the bonds of the gaseous compounds in order to generate nitrogen reactants. These compounds can be cracked either by using high temperatures, for instance, between 700°-1000° C. or by using plasma or ion beam deposition, where high energy nitrogen ions in the gas phase are projected against a material to be coated or covered. The nitrogen reactants then combine with elements at the surface of the material in order to form the nitride film. For example, high quality boron nitride BN films can be formed using diborane (B₂H₆) gas which is passed into a reactor along with hydrazine gas from bubbler.

For example, as disclosed by US 2008/0292798 A1, boron nitride films can be formed that have a dielectric constant between 1.1 and 10, by a deposition method comprising introducing the film precursors into a chamber simultaneously, which boron nitride films have a high step coverage and low pattern loading effect. As defined herein, films with high step coverage have a lower percentage of film thickness difference between different surfaces of a feature, i.e., sidewalls, top, and bottom, than films with low step coverage. The pattern loading effect is defined as the percentage of film thickness difference between a film thickness on portion, such as the bottom, top, or sidewall, of a feature in a substrate region with a few features (an isolated area) and a film thickness on a corresponding portion of a feature in a substrate region with high density of features (a dense area), and thus, a lower pattern loading effect percentage reflects a higher film thickness uniformity across a substrate. The chamber into which the boron-containing precursor is introduced may be any chemical vapor deposition chamber or plasma enhanced chemical vapor deposition chamber. Examples of vapor deposition chambers that may be used include those commercially available from Beneq Oy (Vantaa, Finland) and those available from Applied Materials, Inc. of Santa Clara, Calif.

The boron-containing precursor may be diborane (B₂H₆), borazine (B₃N₃H₆), or an alkyl-substituted derivative of borazine. The boron-containing precursor can be introduced into the chamber with nitrogen (N₂), hydrogen (H₂), argon (Ar) or a combination thereof as a dilution gas. For deposition of the boron-containing film in the absence of a plasma in the chamber, the temperature of a substrate support in the chamber can be set to between about 100° C. and about 1000° C., e.g., specifically between about 300° C. and about 500° C., and the pressure in the chamber can be between about 10 mTorr and about 760 Torr.

After the boron-containing film is deposited, the boron-containing film is treated to modify its composition by incorporating nitrogen oxygen into the film and form a boron nitride or boron oxide film. The treatment can be selected from the group consisting of a plasma process, an ultraviolet (UV) cure process, a thermal anneal process, and combinations thereof, and comprises exposing the boron-containing film to a nitrogen-containing precursor to incorporate nitrogen into the film and form the boron nitride film.

The nitrogen-containing precursor can be nitrogen gas (N₂), ammonia (NH₃), or hydrazine (N₂H₄), for example. The nitrogen-containing precursor can be diluted with a dilution gas such as argon, helium, hydrogen, or xenon. Exposing the boron-containing film to oxygen-containing precursor allows incorporation of oxygen in the film and formation of a boron oxide film. The oxygen-containing precursor can be, for example, oxygen gas (O₂), nitrous oxide (N₂O) or carbon dioxide (CO₂).

In another embodiment, the dielectric layers can be formed by aluminum nitride films having high density, wherein a gas containing aluminum atoms and a gas containing nitrogen atoms is mixed with a gas containing oxygen atoms and fed to a deposition chamber containing the metallic core substrate. For example, U.S. Patent Publication 2012/0100698 A1, hereby incorporated by reference in its entirety, discloses such a process for forming an aluminum nitride film by feeding, into a deposition chamber, a nitrogen-containing gas such as ammonia, an oxygen-containing gas such as O₂, H₂O, NOₓ or COₓ, and a trimethylammonium gas or an aluminum chloride gas, wherein the deposition chamber can be controlled to, for example, a temperature of 1000° C. and a pressure of 100 Pa.

The above-described non-metallic dielectric layers can be designed to provide excellent thermal conductivity and dielectric strength, as well as other desirable electrical properties. The circuit material can have a thermal conductivity of greater than or equal to about 50 Watt per meter-degree Kelvin. Advantageous physical properties can also be obtained, including a z-axis coefficient of thermal expansion of less than or equal to 25 ppm/° C. Furthermore, the non-metallic dielectric layers can provides excellent thermal stability, for example, at operating temperatures of 500° C. or greater. Finally, the non-metallic dielectric layers can provide desirable chemical stability to subsequent processing of the circuit material. Such a balance of properties compares favorably to that found in comparable circuit materials, whether using organic, inorganic, or organic/filler-based dielectric materials. In one embodiment, the non-metallic dielectric layers comprise aluminum oxide or aluminum nitride.

Advantageously, the non-metallic dielectric layers of the present invention can be made using relatively inexpensive materials and manufacture, while providing a superior balance of thermal conductivity, film density, dielectric strength, and/or dielectric breakdown voltage. Furthermore, the process allows opposite sides of the metallic core substrate and the containing walls of the through-hole via to be simultaneously and effectively covered with the same non-metallic material during the same process, referred to as the “ceramicizing” process. This is surprising, particularly given the configuration of the through-hole vias and the risk of short-circuiting if the surface of the metallic core substrate is inadequately insulated. Furthermore, the present process can eliminate the need for the more difficult production of a through-hole via by drilling through both a non-metallic dielectric layer and a metallic core substrate, which can require laser drilling. Instead, the present circuit materials can be made by a process comprising drilling the metallic core substrate, without a ceramic or other inorganic dielectric layer. Thus, mechanical drilling can be used to save the expense of laser drilling, while also limiting the scrap impact of the drilling process to mostly low cost aluminum that has been ceramicized on its surface (and not more expensive substrates consisting of a thermally conductive ceramic material throughout its body.)

A further advantage of the present process is that a circuit material can be manufactured in the form of a panel that has a substantially larger dimension that a current industry of 4.5-inches by 4.5-inches (4.5×4.5 inch) for an LED. In the method of the present invention, it is practical to manufacture a panel that can then be subdivided into multiple panels of such standard size each for use in an HBLED or other LED. Alternatively, larger formats for mounted LEDs can be considered, for example, 8-inch wafers. In contrast, ceramic blanks in the prior art are difficult to manufacture in sizes substantially larger than a 4.5×4.5 format.

The metallic core substrate on which the dielectric layers are to be formed can be advantageously masked such that the non-metallic coating is only deposited to a predetermined region where dielectric functionality is desired. Alternatively, the metallic core substrate can be completely and additively coated with the non-metallic layers. The metallic core substrate can be of any desired shape. Specifically, the metallic core substrate can be a substantially flat thin board such as used in HBLEDs.

The terms metallic or metal, as used herein, are intended to describe broad classes of such material, including semi-metallic compositions. Thus, these terms describe elemental metals such as pure aluminum or magnesium, as well as alloys of one or more elements, and intermetallic compounds. Practically, the metallic core substrates can be commercially available metallic or semi-metallic compositions that can function in the present context. Specifically the metal for the core metal substrate can be aluminum, magnesium, titanium, zirconium, tantalum, beryllium, and an alloys or intermetallic thereof. More specifically, the metal is substantially aluminum or an alloy thereof, specifically predominantly or essentially aluminum.

The terms “non-metallic”, in reference to a dielectric layer or insulation, refers to oxides and/or nitrides of various metal or non-metals, for example, dielectric layers based on the ceramicizing the aluminum metal by a layer of aluminum oxide, aluminum nitride, boron nitride and/or boron oxide, and combinations thereof. Carbide compositions can also be employed. A plurality of layers, for example, 2 to 5, of different compositions can also be employed to provide various properties.

The one or more through-hole vias in the metallic core substrate can be formed by selectively removing metal from the thermally conductive metallic core substrate to create a hole extending from one side to the other side of the metallic core substrate. This can be accomplished prior to formation of the non-metallic dielectric layers. Specifically, the through-hole via can been formed by mechanically drilling through the metallic core substrate. Alternatively, the through-hole via can be formed by etching or laser drilling. Advantageously, therefore, the through-hole via need not be formed by drilling or etching through a hard ceramic dielectric layer, which adds expense and difficulty.

The cross-section of a through-hole via can have various cross-sectional shapes, including circular or non-circular shapes. The through-hole via can have various diameters or equivalent diameters, for example, in the range of 10 to 1000 micrometers, specifically 50 to 500 micrometers, more specifically 100 to 300 micrometers, most specifically 150 to 250 micrometers. The cross-sectional shape and/or dimensions of each of a plurality, or pattern of, through-hole vias can be independently predetermined. In one embodiment, through-hole vias in the circuit material have a circular shape of substantially uniform diameter.

A plurality of vias can be present in the circuit material, for example 1 to 40, specifically 2 to 16, per individual circuit, with 50 to 35,000 circuits per panel, for example, a 4.5 inch by 4.5 inch panel, in order to allow for connections between first and second electrically conductive metal layers. Thus, for example, a circuit material can be made in the form of panel having 1,000 individual circuits, each containing 4 vias resulting in 4,000 vias per 4.5×4.5 panel. In the manufacture of packaged LED's, each panels can be subsequently divided, for example with a diamond blade, into numerous units each having, for example 30 light-emitting diodes for a 60 Watt bulb.

Since the through-hole vias can be formed before the formation of the insulating dielectric layers, so that a dielectric layer can also be formed in the vias, it follows that a later application of an outer adhesion-improving layer (for example, a metallic seed layer) on the dielectric layers can also result in the outer adhesion-improving layer also being present on the dielectric layer on the walls of the through-hole via, as well as under electrically conductive metal applied to the insulated core metallic substrate. Thus, in one embodiment, there is an adhesive-promoting layer, for example, a metallic seed layer, in the through-hole via between the electrically conductive metal-containing core element in the via and the non-metallic layer on the containing walls of the through-hole via, which adhesive-promoting layer can be uniformly and simultaneously applied to the entire surface of the dielectric layers on the thermally conductive core substrate and then removed where copper or other metal plating is not desired. The metallic seed coating can be applied by sputtering, CVD or ALD, specifically, a sputtered metallic seed layer.

The non-metallic dielectric layers can have a thickness to provide the desired breakdown performance for insulating the metal core substrate in the particular application. In one embodiment, the dielectric substrate has a thickness of about 1 to 50 micrometers (about 0.04 mils to about 2 mils), specifically about 1 to 15 micrometers, more specifically 0.13 to about 0.6 mils (about 5 to about 15 micrometers). In an embodiment, the thicknesses, on average, of the first and second dielectric layers on the opposite sides of the metallic core substrate and in the through-hole vias can be substantially uniform, for example, within 50 percent, more specifically within 25 percent, most specifically within 10 percent of each other. Thus, non-uniform surface loading can be avoided.

In one embodiment, the thickness of the non-metallic dielectric layers is specifically less than 40 micrometers, and specifically less than 20 micrometers, more specifically less than 15 micrometers. The thinner the non-metallic dielectric layer, the more effective the thermal transfer across the layer. Thus, it can be advantageous to provide a non-metallic dielectric layer having thicknesses even lower, for example, 1 micrometer to 15 micrometers.

A circuit material according to an aspect of the invention can comprise non-metallic dielectric layers that have been applied selectively to a portion of a metallic core substrate or to the entire metallic core substrate. Accordingly, in one embodiment, the non-metallic dielectric insulation on the metallic core substrate is formed by a method comprising positioning a metallic core substrate, having one or more through-hole vias formed therein, in a deposition chamber. The metallic core substrate can be, for example, in the form of a circuit board, specifically a thin panel having at two substantially flat sides in which one or more through-hole vias have been drilled or otherwise made. At least the surface of the metallic core substrate on which it is desired to form a non-metallic dielectric layer, specifically both sides of the metallic core substrate and the containing walls of the through-hole via are in contact with CVD or ALD co-reactants.

In one embodiment, for improved inner adhesion of the non-metallic insulation, the metal core substrate has been pretreated by electrolytic oxidation to produce an initial or preliminary metal oxide coating such as aluminum oxide. For example, conventional anodizing, suitably optimized, can be used to form a metal oxide dielectric layer on the metallic core substrate, as well be appreciated by conventional anodizing. Still another method of oxidizing the surface of the metallic core substrate is by plasma electrolytic oxidation (PEO), which is a kind of anodizing as will be understood by the skilled artisan. In one specific type of electrolytic pretreatment, a sequence of voltage pulses of alternating polarity can be applied for a predetermined period to the metal core substrate in an electrolytic reactor containing an aqueous electrolyte and an electrode. Positive voltage pulses anodically bias the substrate with respect to the electrode, and negative voltage pulses cathodically bias the substrate with respect to the electrode. The amplitude of the positive voltage pulses can be potentiostatically controlled, that is controlled with respect to voltage, and the amplitude of the negative voltage pulses can be galvanostatically controlled, that is controlled by reference to current. Such a method of forming a non-metallic dielectric layer in the present circuit materials is, for example, disclosed in detail in WO 2012/1077555 and WO 2012/107754, which publications are hereby incorporated by reference in their entirety. By applying a sequence of voltage pulses of alternating polarity in which positive pulses are potentiostatically controlled and negative pulses are galvanostatically controlled, pulses of high voltage can be applied to the core metal substrate without inducing substantial levels of micro-discharge. By minimizing or avoiding micro-discharge events during the formation of non-metallic dielectric layers, surface roughness and the magnitude of the coating porosity can be controlled. This has been found to effectively and continuously coat the hole-through vias, despite their finely shaped nature, with an insulating layer of non-metallic, such that short circuits are avoided in the vias during operation of a mounted electronic device. Furthermore, single or continuous plating operation can, at the same time, “coat” the opposite sides of the metal substrate layer and through-hole vias, rather than necessitating separate or independently conducted unit operations, which makes for a very efficient manufacture. The method of forming the metal oxide adhesion-promoting preliminary coating can be carried out in an electrolyte that is an alkaline aqueous solution, specifically an electrolyte having a pH of 9 or greater. Specifically, the electrolyte has an electrical conductivity of greater than 1 mS cm⁻¹. Electrolytes can include alkaline metal hydroxides, particularly those comprising potassium hydroxide or sodium hydroxide. The electrolyte can be colloidal and comprise solid particles dispersed in an aqueous phase, wherein the electric field generated during the applied voltage pulses can cause electrostatically charged solid particles dispersed in the aqueous phase to be transported towards the surfaces of the metallic core substrate on which the metal oxide layers are beginning to grow by oxidation. As the solid particles come into contact with the growing metal oxide layers, they can react with and/or physically intermix with, and become incorporated into the preliminary layer.

The method of forming the preliminary metal-oxide adhesion-promoting layer, as described above, can be for a predetermined time. In particular, the process can be carried out for a time required to provide a desired or preselected thickness of the metal-oxide. In one embodiment, the predetermined time can be between 1 minute and 1 hour, specifically 1 to 20 minutes. The rate of development of the layers of metal oxide material can depend on a number of factors including voltage, the waveform used to bias the substrate relative to the electrode, and/or the density and size of particles in the colloidal electrolyte when the method employs a colloidal electrolyte, as well as the time involved.

Following optional pretreatment, the metallic core substrate can be introduced into a deposition apparatus suitable for depositing non-metallic dielectric layers on the surface of the metallic core substrate. As would by appreciate by the skilled artisan, a deposition chamber can comprise one or more inlets for co-reactants and an outlet for carrier gas.

It is desirable to eliminate porosity in the non-metallic insulation, which can contribute to desired and beneficial mechanical and electrical properties and allow for more effective insulation of through-hole vias. For example, a low average pore diameter can improve the dielectric strength of a layer. A high dielectric strength can mean that the non-metallic dielectric thickness required to achieve a predetermined minimum dielectric strength for a particular application can be lowered, which in turn can improve the thermal conductivity of the layer. Furthermore, a lower pore size can also improve the thermal conductivity of a non-metallic dielectric layer by improving the heat flow path through the layer

The electrically conductive metal layers that are disposed on the non-metallic dielectric layers are desirably both electrically conducting and thermally conducting. Useful electrically conductive metal layers for the formation of the circuit materials disclosed herein include stainless steel, copper, nickel plated copper, aluminum, copper-clad aluminum, zinc, zinc-clad copper, iron, transition metals, and alloys comprising at least one of the foregoing, with copper specifically useful and herein representative of an electrically conductive metal. There are no particular limitations regarding the thickness of the electrically conductive metal layers, nor are there any limitations as to the shape, size or texture of the surface of the conductive metal layer. In an exemplary embodiment, the conductive metal layer has a thickness of about 3 micrometers to about 200 micrometers, specifically about 5 micrometers to about 180 micrometers, and more specifically about 7 micrometers to about 75 micrometers. Where two or more conductive metal layers are present, the thickness of the two layers can be the same or different.

Electrically conductive metal layers comprising plated metals, specifically electroplated coppers, are particularly useful.

In one embodiment, the first and second electrically conductive metal layers, as well as the metal-containing core element in the through-hole via comprises copper. Copper plated electrically conductive metal layers can be further coated with silver or gold. The first and second conductive metal layers can have a total thickness of 1 to 250 micrometers, while the metallic core substrate can have a thickness of 0.5 to 1.5 mm, specifically 0.38 to 1.0 mm, corresponding to that of the through-hole vias present.

The first electrically conductive metal layer and the second electrically conductive metal layer, on opposite sides of the metallic core substrate, can be formed by a process selected from screen printing, metal ink printing, electroless metallization, galvanic metallization, chemical vapor deposition (CVD), and plasma vapor deposition (PVD) metallization. Thus, metallic foils or flex circuits can be eliminated. The electrically conductive metal layers can be patterned, as discussed further below, or un-patterned. The circuit material can advantageously be in the form of a panel having an area that is 15 to 20 times the area of a conventional panel that is 4.5 inches by 4.5 inches (ceramic blanks having an image area of 4 inches by 4 inches). Subsequently, such larger panel can be divided into individual units or used for making larger individual panels. For example, a circuit material that is 14 by 22 inches can be produced. A panel that has 14 inch by 22 inch dimensions, for example, can allow for an array of 3×5 panel images or the equivalent of 15 of the 4.5 inch×4.5 inch panels.

In general, the circuit material can be made by a method that overall comprises providing an metallic core substrate that is thermally conductive, forming at least one through-hole via in the metallic core substrate, forming non-metallic dielectric layers on opposite sides and in the through-hole via of the metallic core substrate by a deposition process comprising CVD or ALD, and then applying copper or other electrically conductive metal over the surface of at least thus formed vapor-deposited non-metallic dielectric layers on the opposite sides of the metallic core substrate. (In the following discussion of the method, copper will be used to represent an electrically conductive metal, but it is to be understood not to limit the method to copper.)

In one embodiment, the through-hole via can be filled with a metal-containing core element electrically connecting the electrically conducive layers on opposite sides of the metallic core substrate during the plating of the electrically conductive metal layers, thereby forming a metal-containing core element that is bulk metal. Alternatively, the through-hole via can filled with a metal-containing core element electrically connecting the electrically conducive layers on opposite sides of the metallic core substrate following application of the electrically conductive metal layers, wherein the metal-containing core element is made by filling the through-hole via with metallic paste comprising metal particles and an organic resin, as will be appreciated by the skilled artisan. Thus, the through-hole vias can be filled after plating the electrically conductive metal layers, before, or at the same time. The first non-metallic dielectric layer, the second non-metallic dielectric layer, and/or the dielectric layer in the through-hole via can be coated with an outer adhesion-improving material, specifically after forming the non-metallic dielectric layers and before applying copper over the surface of the non-metallic dielectric layers. For example, a metallic seed layer can be coated onto the surface of the non-metallic dielectric layer in order to promote adhesion, or initiate plating, of the electrical conductive metal that is subsequently applied to form the electrically conductive metal layers. In one embodiment the metal seed layer is a sputtered layer comprising titanium (Ti) having a thickness of 100 to 150 nanometers, followed by 1-2 microns of copper (Cu).

In an embodiment, the method of making a circuit material can further comprise, after forming non-metallic dielectric layers and optionally coating with an adhesion-enhancing material, but before plating or otherwise applying copper, applying a resist coating to the coated or uncoated non-metallic dielectric layer, exposing the resist, and developing the resist. Accordingly, after plating copper onto the surface of the non-metallic dielectric layers, the resist can be stripped to produce a patterned electrically conductive metal layer. Alternatively, copper or other metal could be plate unpatterned and then selectively patterned by printing and etching the copper. Additive plating, however, can be more cost effective.

In the event that an optional metallic seed layer is applied (for example by ALD, CVD, or sputtering) onto the surface of the dielectric layers to improve the adhesion of the subsequent copper layer, the metallic seed layer can be removed (by etching, for example), after plating and patterning the copper onto the surface of the non-metallic dielectric layer.

In one embodiment, the method of making the circuit material comprises, after forming non-metallic dielectric layers, coating the layers with a metallic seed layer and, before applying the electrically conductive metal layers, applying a resist coating to the coated non-metallic dielectric layers, exposing the resist, developing the resist, plating electrically conductive metal layers over the non-metallic dielectric layers in areas where the resist has been developed, stripping the resist, and removing the metallic seed layers from areas that have not been plated with electrically conductive metal layers. In an alternative embodiment, the through-hole via can be filed with a metal paste, for example, a copper paste, and the electrically conductive metal layers on opposite sides of the metallic core substrate screen printed. The method can further comprise plating the surface of the copper layer with another metal, for example silver in order to protect the copper form ceramicizing and provides improved solderability. Subsequently, after plating one or more metals onto the surface of the non-metallic dielectric layers, a solder stop layer can be applied, as would be appreciated by the skilled artisan.

The method can further comprise, after plating copper onto the surface of the non-metallic dielectric layer, dividing the circuit material into a plurality of separate panels, each of which is about 4.5 inches by 4.5 inches (or within 50 percent, specifically within 30 percent, more percent within 10 percent of each dimension), as is a standard size for an individual LED unit or package.

The method can further comprise, after plating copper onto the surface of the insulated metallic core substrate, mounting an electronic device onto a surface of the circuit material to provide a product unit comprising the electronic device. In one embodiment, the electronic device can be an HBLED, as further discussed below.

In a more specific embodiment, the method of making a circuit material can comprise providing a metallic core substrate that is thermally conductive, drilling or otherwise forming at least one through-hole via in the metallic core substrate. In addition to forming the vias, perforations can also be provided in the substrate preparatory to singulation or division of the substrate into individual panels, as discussed herein. Thereafter, non-metallic dielectric layers are formed on opposite sides and in the via of the metallic core substrate by a process comprising vapor deposition of a non-metallic dielectric material on the metallic core substrate, optionally coating the non-metallic dielectric layers with an inorganic outer adhesion-improving material, wherein the method further comprises patterning electrically conductive metal layers. Optionally, prior to vapor deposition, the metallic core substrate can be oxidatively pretreated by to improve adhesion of the vapor deposited material. The conductive metal layers can be patterned, in one embodiment, by applying a resist coating to the seed layer coated non-metallic dielectric layers and then, after exposing and developing the resist, plating copper over the surface of the non-metallic dielectric layers, stripping the resist, and then etching or otherwise removing the inorganic outer adhesion-improving material (for example, a sputter coated metal seed layer) from the non-plated areas of the non-metallic dielectric layers. In the event of coating the non-metallic dielectric layers with an inorganic outer adhesion-improving layer that comprises a sputter coated metallic seed layer, for promoting adhesion of copper to a dielectric layer, the metallic seed layer can be subsequently removed from the non-plated areas of the non-metallic dielectric layers, in order to prevent a short circuit.

The dielectric strength of the non-metallic dielectric layers (and hence the circuit material) can be determined by measuring the dielectric breakdown voltage at multiple points on a sample, which is done by applying a voltage across two electrodes in intimate contact with either of the surfaces of the dielectric material and the inner core metal, such that the electrodes are separated by a distance equal to the thickness of the non-metallic dielectric layer at the point of measurement, wherein access for an electrode under the dielectric layer can be gained through the side or by removing a portion of the non-metallic layer. A direct current potential is placed across the electrodes, and the resistance to the voltage flow is measured as the voltage is increased. The voltage at which current begins to flow between the electrodes is noted as the dielectric breakdown voltage, and is measured in volts per mil of thickness (V/mil) or V/mm. Different dielectric breakdown voltages are associated with different materials of construction, and can vary depending on the composition of the dielectric layer, including the metal of the thermally conductive metal, the process of making converting a surface portion to a dielectric layer, and other compositional or processing factors. Thickness uniformity can also affect the dielectric breakdown voltage, with thinner regions showing lower dielectric breakdown voltages. In any case, however, continuous and effective coverage, as necessary, is important to prevent a short circuit.

In an embodiment, the circuit material can be supplied to a fabricator for attachment to a surface to provide a pathway for further heat dissipation away from the electronic device (e.g., a semiconductor device). Examples of such surfaces include surfaces of heat sinks and the like. Any suitable means can be used to attach the thermal management circuit material, or a circuit derived therefrom, to the surface. In an embodiment, the thermal management circuit material can be attached to a surface using a suitable thermally conducting layer or treatment, such as a thermally conducting adhesive. Such thermally conductive adhesives, where used, can be electrically conductive, semiconducting, or electrically non-conductive.

In an embodiment, the circuit material can be attached to a thermally conductive heat sink or the like that is substantially thicker than the metallic core substrate layer and that comprises a metal having a high thermal conductivity. Suitable metals having such characteristics include aluminum, copper, aluminum clad copper, and the like; or engineered thermal materials such as AlSiC, Cu/Mo alloys, and the like. Such thermally conductive heat sinks can comprise a single layer, multiple layers of a single material, or multiple layers comprising two or more different materials. The heat sink can be of a single uniform thickness, or can be of variable thickness. The thermally conductive base layer can include features such as cooling fins, tubes, or have tubes bored through the heat sink, through which a coolant can be passed to further increase the transfer of heat.

In a further embodiment, at least one additional layer including a dielectric layer, bond ply, conductive metal layer, a circuit layer, or a combination comprising at least one of the foregoing, can be disposed on the patterned electrically conducive layer, or circuit, in an appropriate manner to form a multilayer circuit.

The circuit materials described herein can have excellent properties, for example good dimensional stability and enhanced reliability, e.g., plated through-hole reliability, and excellent copper (metal) peel strength, particularly at high temperature.

In an embodiment, the circuit materials, specifically the non-metallic dielectric layers, are thermally stable at a temperature of greater than or equal to 150° C., specifically greater than or equal to 400° C., more specifically to 500° C. or more. Especially for use in combination with high power type solid-state devices, the circuit material can possess thermal properties that can tolerate exposure to temperatures encountered during processing operations such as soldering, brazing and welding. Temperatures of about 400° C., in either inert or hydrogen atmospheres, can be encountered. Typically, soldering operations are lower in temperature at about 200° C., while brazing operations can have higher temperatures in excess of about 425° C. Formation of copper oxide as a result of use with these high temperature processes can be mitigated by using a plating of a metal such as nickel, zinc, or other suitable metal that can mitigate the formation of oxides on the copper surface.

The circuit material having non-metallic dielectric layers can exhibit excellent resistance to chemicals encountered in printed circuit processes, as well as resistance to mechanical failures that can be caused by cutting, molding, broaching, coining or folding, which can result in damage such as cutting, ripping, cracking, or puncturing of one or more layers. The mechanical and electrical properties of the circuit material can provide an electrical mount that can withstand the processing conditions expected during subsequent assembly and during functional operation of the end product. For example, the circuit material can withstand exposure to chemicals encountered during printed circuit fabrication and the finished product can be mechanically durable enough to withstand mounting techniques and conditions, for example, in LED manufacture,

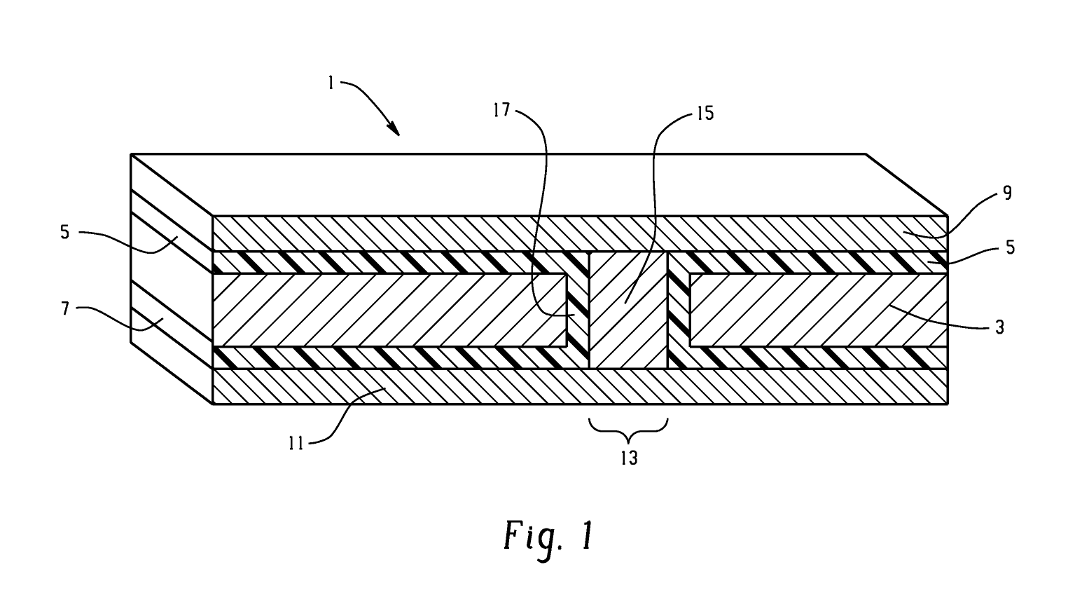

FIG. 1 is a cross-section of a thermal management circuit material and made according to one embodiment of a process of making the circuit material. Referring to FIG. 1, the circuit material 1 comprises a thermally conductive metallic core substrate 3, a first non-metallic dielectric layer 5 on a first substantially flat side of the metallic core substrate 3; and a second non-metallic dielectric substrate layer 7 on a second side of the thermally conductive metallic core substrate, which second side is opposite from the first side of the metallic core substrate. The non-metallic dielectric layers have been formed by reactive vapor deposition. A first electrically conductive metal layer 9 (unpatterned in this embodiment) comprises a conductive metal, for example copper, on the first non-metallic dielectric layer 5. A second conductive metal layer 11 is disposed on the second non-metallic dielectric layer 7.

A through-hole via 13 is filled, for example plated, with an electrically conductive metal, which can also be copper, thereby at the same time forming, in the through-hole via, a metal-containing core element 15 that can electrically connect at least a portion of each of the first and second electrically conductive metal layers 9 and 11, wherein the through-hole via 13 is formed in (defined by) the thermally conductive metallic core substrate (and its non-metallic dielectric layer) and extending from one side to the other thereof.

Thus, the containing walls defining the through-hole via are covered with an intermediate or third non-metallic dielectric layer 17 that physically joins (continuously connects) the first non-metallic dielectric layer 9 to the second non-metallic dielectric layer 11, without containing gaps that could cause a short-circuit.

As mentioned above, an optional outer adhesion-improving layer, such as a metallic seed layer, of substantially lesser thickness than the non-metallic dielectric layers, specifically less than one-fourth the thickness of the dielectric layers, can be applied over the non-metallic dielectric layers prior to application of the electrically conductive metal layers. Hence, in the thermal management circuit material of FIG. 1, an outer adhesion-improving layer (not shown) can be present between the first electrically conductive metal layer 9 and the first non-metallic dielectric layer 5, between the second conductive metal layer 11 and the second non-metallic dielectric layer 7, and between the non-metallic layer 17 of the through-hole via 15 and the electrically conductive metal-containing core element 15 in the through-hole via 13. In one embodiment, the outer adhesion-improving layer is a metallic seed metal that comprises sputtered metal, for example copper and/or titanium. Similarly, the optional inner adhesion-improving layer, such as a formed by electrolytic oxidation, can be of substantially lesser thickness than the non-metallic dielectric layers, specifically less than one-fourth the thickness of the dielectric layers.

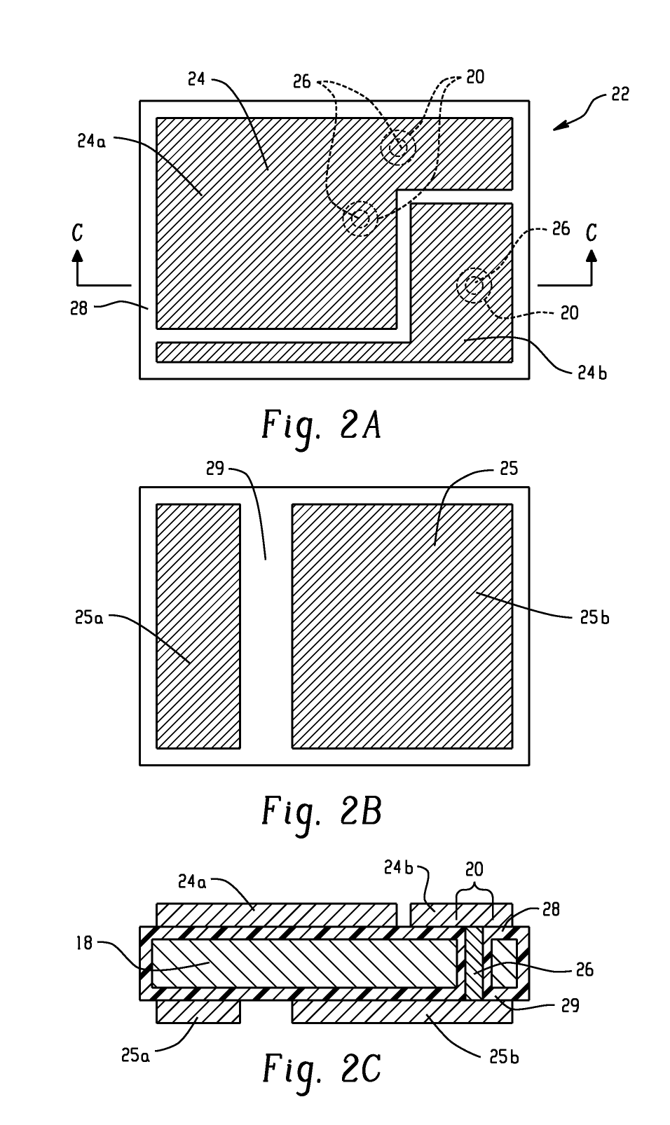

FIGS. 2A to 2C show a thermal management circuit material that can be used as a submount for an LED device package and which comprises a metallic core substrate 18 drilled with a plurality of through-hole vias 20 capable of being drilled prior to the formation of the non-metallic dielectric layer and copper plating. FIG. 2A shows a top plan view of the thermal management circuit material shown in bottom view in FIG. 2B and cross-sectional view (along line C-C of FIG. 2B) in FIG. 2C. In particular, FIG. 23A shows a top plan view of one embodiment of a thermal management circuit material 22 plated with a first electrically conductive metal layer 24, patterned into portions 24a and 24b, and second electrically conductive metal layer 25, patterned into portions 25a and 25b. In FIG. 2A, dotted lines indicate the location of a plurality of through-hole vias 26 under the first electrically conductive metal layer 24, portions of which are divided by areas of the first non-metallic dielectric layer 28. In FIG. 2B, the second non-metallic dielectric layer 29 can be seen in bottom view. In FIG. 2C, the through-hole via 20 filled with a metal-containing core element 26 is evident.

For certain applications, circuit materials can have a multilayered structure. For example, an additional layer or layers of dielectric material and associated metal conducting layers (not shown) can then be formed on the top of first and/or second electrically conductive metal layers 9 and 11 in the circuit material of FIG. 1. The additional dielectric layer or layers can comprise, for example, FR-4 fiberglass laminates or comprise an organic resin which, for example, can be selected from the group consisting of fluoropolymer, polyimide, polybutadiene, polyisoprene, poly(arylene ether) and combinations thereof. A multilayered structure formed on a base circuit material can enable a large number of external connections to be made.

As mentioned above, an electronic device can advantageously be attached to a thermal management circuit material such as shown in FIG. 2B, in order to provide high thermal conductivity. Thus, another aspect of the invention is directed to articles comprising an electronic device, for example, an optoelectronic device, an RF device, a microwave device, a power switch, a power amplifier, or other heat-generating component of a circuit, which electronic component or device can be supported on the first electrically conductive metal layer of the circuit material. Specifically, the electronic device can be type of semiconductor, for example, an LED, an HBLED, a MOSFET (metal-oxide-semiconductor field-effect transistor, an IGBT (insulated-gate bipolar transistor), or other heat-generating components for power applications, as would be appreciated by the skilled artisan. In certain applications, the article can comprises RF components, wherein circuits formed on the surface of the circuit material comprise high-Q input/output transmission lines, RF de-coupling and matching circuits.

In the case of an LED device (including specifically an HBLED), the LED device can be electrically connected to at least a portion of the first electrically conductive metal layer, for example, either by a metal wire or in a flip chip arrangement. Each of two ends of an LED can be sequentially connected to a voltage source to provide power to the LED. In one embodiment, a first electrically conductive metal layer and a second electrically conductive metal layer can be patterned and wires from the LED device can be connected to a first and second contact portion of the first electrically conductive metal layer. Furthermore, at least one conductive through-hole via can electrically connect each of the first and second contact portions to corresponding contact portions of the second electrically conductive metal layer on the circuit material.

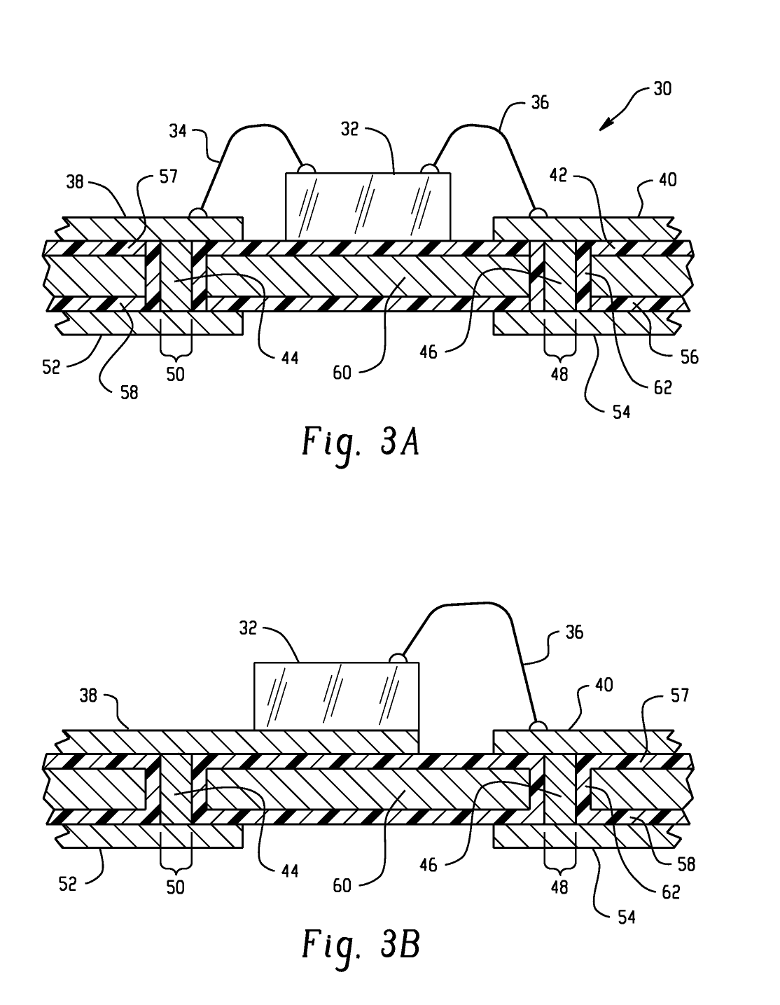

An LED device (“chip”) can be attached directly to the non-metallic dielectric layer on the thermally conductive metal core substrate, which non-metallic dielectric layer provides electrical insulation between the chip and the metallic core substrate or the LED device can be supported by an electrically isolated thermal or support pad on a non-metallic dielectric layer, which is isolated from the anode or cathode of the LED. The thickness of the non-metallic layer can be determined by the breakdown voltage requirement of the chip, and can be grown to the minimum thickness that meets the breakdown voltage requirement. This can provide the shortest thermal path between semiconductor components in the chip, which generates heat, and the metallic core substrate. FIGS. 3A and 3B show two different exemplary embodiments of an article 30 having an LED package or unit mounted on a base thermal management circuit material. The corresponding features in FIGS. 3A and 4B are correspondingly numbered. In the embodiment of FIG. 3A, an LED device 32 is disposed (mounted) on a circuit material that includes wire leads 34 and 36 electrically connected to contact pads 38 and 40, part of a first electrically conductive metal layer 42. Metal core elements 44 and 46 fill each of the through-hole vias 48 and 50 and electrically connect the electrical contact pads 38 and 40 in the first electrically conductive metal layer 42 to, respectively, electrical contact pads 52 and 54 in a second electrically conductive metal layer 56, which electrical contact pads can be part of a patterned circuit comprising plated copper. Integrally connected and substantially uniform non-metallic dielectric layers 57 and 58 on opposite sides of metallic core substrate 60, and cylindrically shaped intermediate non-metallic dielectric layer 62, insulate electrically conductive metal from the thermally conductive metallic core substrate 60. As discussed above, the dielectric layers are non-metallic layers that can be deposited to ceramicize at least a surface areas portion of the metallic core substrate.

The embodiment of FIG. 3B show a flip chip arrangement in which an LED device 32 is supported on an electrical contact pad 38 of the first electrically conductive metal layer 42. One end of the LED has a wire 36 electrically connected to electrical contact pad 40 of the first electrically conductive metal layer 42. Metal core elements 44 and 46 fill each of the through-hole vias 48 and 50 and electrically connect the electrical contact pads 38 and 40 in the first electrically conductive metal layer to, respectively, electrical contact pads 52 and 54 in a second electrically conductive metal layer, which contact pads can be part of a patterned circuit comprising plated copper. Dielectric layers 56, 58, and 62 insulate the electrically conductive metal from the thermally conductive metallic core substrate 60, as discussed with respect to the embodiment of FIG. 3A.

The singular forms “a,” “an,” and “the” include plural referents unless the context clearly dictates otherwise. The endpoints of all ranges directed to the same characteristic or component are independently combinable and inclusive of the recited endpoint. All references are incorporated herein by reference. As used herein and throughout, “disposed,” “contacted,” and variants thereof refers to the complete or partial physical contact between the respective materials, substrates, layers, films, and the like. Further, the terms “first,” “second,” and the like herein do not denote any order, quantity, or importance, but rather are used to distinguish one element from another.

While typical embodiments have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

What is claimed is:

1. A thermal management circuit material, capable of use for mounting an electronic device, comprising:
a thermally conductive metallic core substrate;
a first non-metallic dielectric layer on a first side of the metallic core substrate;
a second non-metallic dielectric substrate layer on a second side of the thermally conductive metallic core substrate, which second side is opposite from the first side of the metallic core substrate;
a first electrically conductive metal layer on the first oxide non-metallic dielectric layer;
a second electrically conductive metal layer on the second non-metallic dielectric layer;
at least one through-hole via filled with an electrically conductive metal forming a metal-containing core element that electrically connects at least a portion of each of the first and second electrically conductive metal layers, wherein the walls defining the through-hole via have an intermediate non-metallic dielectric layer transversely joining the first non-metallic dielectric layer and the second non-metallic dielectric layer, which intermediate non-metallic dielectric layer insulates the metal-containing core element in the through-hole via from the thermally conductive metal core substrate;
wherein the first, second, and intermediate non-metallic dielectric layers are made by a process comprising depositing the reaction product of volatile precursor compounds on at least a surface area portion of the metallic core substrate, wherein the deposited reaction product comprises a non-metallic compound selected from the group consisting of a metal oxide, metal nitride, boron oxide, boron nitride, and combinations.

2. The circuit material of claim 1 wherein the non-metallic dielectric layers are made by CVD or ALD.

3. The circuit material of claim 1 wherein the non-metallic dielectric layers comprise a material selected from the group consisting of aluminum oxide, boron oxide, aluminum nitride, boron nitride, and combinations thereof.

4. The circuit material of claim 1 wherein the first and second non-metallic dielectric layers have a thermal conductivity of greater than or equal to about 5 Watt per meter-degree Kelvin and a dielectric strength of greater than or equal to about 20 KV per mm.

5. The circuit material of claim 1 wherein the first and second non-metallic dielectric layers each have a thickness of 1 to 15 micrometers.

6. The circuit material of claim 1 wherein the thermally conductive metallic core substrate has a thickness of 0.25 to 3.0 mm.

7. The circuit material of claim 1 wherein the circuit material, having patterned or unpatterned electrically conductive metal layers, forms a panel having an area that is 15 to 20 times the area of a conventional panel that is 4.5 inches by 4.5 inches.

8. The circuit material of claim 1 wherein the metallic core substrate comprises aluminum or an alloy of aluminum with one or more metals selected from the group consisting of magnesium, titanium, zirconium, tantalum, and beryllium.

9. The circuit material of claim 1 further comprises an outer adhesion-improving layer directly bonding the first electrically conductive metal layer to the first non-metallic dielectric layer, the second electrically conductive metal layer to the second non-metallic dielectric layer, and the electrically conductive metal-containing core element in the via to the intermediate non-metallic dielectric layer.

10. The circuit material of claim 9 wherein the outer adhesion-improving layer is a metallic seed layer for plating of the electrically conductive metal layers, which metallic seed layer of substantially lesser thickness than the non-metallic layer on which it is coated.

11. The circuit material of claim 1 wherein there is a layer of sputtered metallic seed metal in the through-hole via between the electrically conductive metal forming the metal-containing core element in the via and the intermediate non-metallic layer forming the walls of the through-hole via.

12. The circuit material of claim 1 wherein the metal core substrate has been made by a process that comprises pre-treating by electrolytic oxidization, to a preselected depth, at least a surface area portion of the metal core substrate prior to depositing the non-metallic dielectric layers.

13. An article comprising a heat-generating electronic device mounted on the circuit material of claim 1.

14. The article of claim 13 wherein the electronic device is selected from the group consisting of an optoelectronic device, an RF device, or a microwave device, a switching or amplifying semiconductor, or a power transistor, wherein the electronic device is supported on the first electrically conductive metal layer of the circuit material.

15. The article of claim 14, wherein the electronic device is an LED.

16. A method of making a circuit material comprising providing a metallic core substrate that is thermally conductive;
forming at least one through-hole via in the metallic core substrate;
forming non-metallic dielectric layers on opposite sides and in through-hole vias of the metallic core substrate by depositing on the surface of the metallic core substrate a non-metallic material; and
applying electrically conductive metal layers over the surface of the non-metallic dielectric layers at least on opposite sides of the metallic core substrate.

17. The method of claim 16, wherein the non-metallic dielectric layers have been formed, in a deposition chamber, by chemical vapor deposition or atomic layer deposition.

18. The method of claim 16, wherein the non-metallic dielectric layers have been formed, in a deposition chamber, by chemical vapor deposition or atomic layer deposition of aluminum oxide comprising: (a) providing an aluminum alkoxide precursor that is dissolved, emulsified or suspended in a liquid; (b) providing a vapor generated from the aluminum alkoxide precursor; and (c) depositing an aluminum oxide film from said vaporized precursor on a substrate.

19. The method of claim 18, wherein the chemical vapor deposition or atomic layer deposition of aluminum oxide further comprises introducing into the deposition chamber, separately from said vaporized aluminum alkoxides, an oxidizing reactant.

20. The method of claim 19, wherein said oxidizing reactant is selected from the group consisting of oxygen, ozone, water, hydrogen peroxide, nitrous oxide, and combinations thereof.

21. The method of claim 18, wherein the non-metallic layers comprise a boron nitride film or boron oxide film made by introducing a boron-containing precursor into a deposition chamber holding the metallic core substrate, depositing a boron-containing film onto the metallic core substrate in the chamber from the boron-containing precursor; treating the boron-containing film to increase the nitrogen or oxygen content in the film, thereby forming a boron nitride film or boron oxide film; and repeating the introducing, depositing, and treating until a desired thickness of the boron nitride film or boron oxide film is obtained.

22. The method of claim 21, wherein said treating comprises exposing the boron-containing film to a nitrogen-containing or oxygen-containing precursor.

23. The method of claim 22, wherein the oxygen-containing precursor is selected from the group consisting of oxygen gas, nitric oxide (NO), nitrous oxide (N₂O), carbon dioxide (CO₂), and water (H₂O) and the boron-containing precursor is selected from the group consisting of diborane, borazine, and alkyl-substituted derivatives of borazine.

24. The method of claim 22, wherein the nitrogen-containing precursor that is selected from the group consisting of ammonia, nitrogen gas, and hydrazine.

25. The method of claim 16 wherein the through-hole via is filled with a metal-containing core element electrically connecting the electrically conducive layers on opposite sides of the metallic core substrate during the plating of the electrically conductive metal layers.

26. The method of claim 16 wherein the through-hole via is filled with a metal-containing core element electrically connecting the electrically conducive layers on opposite sides of the metallic core substrate following application of the electrically conductive metal layers, wherein the metal-containing core element is made by filling the through-hole via with a metallic paste comprising metal particles and an organic resin.

27. The method of claim 16 wherein, after forming the non-metallic dielectric layers and before applying electrically conductive metal over the surface of the non-metallic dielectric layers, coating a metallic seed layer onto the surface of the non-metallic layers.

28. The method of claim 16 further comprising, after applying metal layers onto the surface of the non-metallic dielectric layers, dividing the circuit material into a plurality of smaller panels each having dimensions within the range of about 4.0 to 5.0 inches on each of two sides.

29. The method of claim 16, wherein the metal layers are patterned and wherein the method further comprises mounting high-brightness light-emitting diode onto the patterned circuit material.
